(19) United States
(12) Patent Application Publication
(10) Pub. No.: US 2015/0240899 A1
(43) Pub. Date: Aug. 27, 2015

(54) AIRCRAFT BRAKE DISC AND METHOD FOR MAKING THE SAME

(71) Applicant: DACC CARBON, Jeonju-si (KR)

(72) Inventors: Chae Wook CHO, Daejeon (KR); Jong Hyun PARK, Jeonju (KR); Cheol Su YUN, Jeonju-si (KR); Kap Su JUNG, Jeonju (KR); Gi Bum RYU, Gunsan-si (KR)

(21) Appl. No.: 14/580,806

(22) Filed: Dec. 23, 2014

(30) Foreign Application Priority Data
Feb. 25, 2014 (KR) 10-2014-0022212

(51) Int. Cl. F16D 69/02; F16D 55/24; C23C 16/04; F16D 65/12

(52) U.S. Cl. CPC F16D 69/023; F16D 65/126; F16D 55/24; C23C 16/045

(57) ABSTRACT

An aircraft brake disc includes a pressure disc and a rear disc that are disposed at both ends, respectively, and rotary discs and fixing discs that are alternately disposed between the pressure disc and the rear disc, in which drive key grooves that are fitted to drive keys of an aircraft wheel frame are formed with regular intervals around the rotary disc, spline grooves that are fitted to splines of a torque tube of an aircraft brake system are formed with regular intervals around the inner side of a hole of the fixing disc, and the drive key grooves and the spline grooves are coated with an anti-oxidation coating solution including a metal buffer.

### CROSS-REFERENCE TO RELATED APPLICATIONS

This application claims the priority of Korean Patent Application No. 10-2014-0022212 filed on Feb. 25, 2014, in the Korean Intellectual Property Office, the disclosure of which is incorporated herein by reference.

### BACKGROUND OF THE INVENTION

1. Field of the Invention

The present invention relates to an aircraft brake disc and the method of manufacturing the same.

2. Description of the Related Art

The background of the present invention has been disclosed in Korean Patent No. 10-0447840.

An aircraft brake disc is composed of a pressure disc, a rear disc, and rotary discs and fixing discs that are alternately disposed between the pressure disc and the rear disc.

The pressure disc, the rear disc, the rotary disc, and the fixing disc increase in temperature over 1000° C. due to friction therebetween, when an aircraft is landing. The pressure disc, the rear disc, the rotary disc, and the fixing disc are made of a carbon-carbon composite to maintain friction or mechanical strength against the high temperature.

The carbon-carbon composite is a material that keeps friction or mechanical strength even at a high temperature over 2500° C. and has excellent resistance against thermal shock and excellent thermal conductivity.

The rotary disc is coupled to a drive key of a wheel frame of an aircraft and rotates with the wheel frame. The fixing disc is coupled to the splines of a torque tube included in an aircraft brake system, so it does not rotate with the wheel frame of an aircraft.

Larger torque and shock are applied to the portion coupled to a drive key of the rotary disc than other portions of the rotary disc, when a brake system is operated. Accordingly, the portion coupled to a drive key of the rotary disc is easier to crack or break than other portions of the rotary disc. When the portion coupled to a drive key of the rotary disc starts cracking or breaking, the entire rotary disc consequently breaks and cannot be used.

Similarly, larger torque and shock are applied to the portion coupled to splines of the fixing disc than other portions of the fixing disc, when a brake system is operated. Accordingly, the portion coupled to splines of the fixing disc is easier to crack or break than other portions of the fixing disc. When the portion coupled to splines of the fixing disc starts cracking or breaking, the entire fixing disc consequently breaks and cannot be used.

In order to solve those problems, metal clips are attached to the portion coupled to a drive key of the rotary disc and the portion coupled to splines of the fixing disc in order to protect the rotary disc and the fixing disc against torque and shock.

However, it is difficult to sufficiently protect the rotary disc and the fixing disc against torque and shock, only with the metal clips.

### SUMMARY OF THE INVENTION

An aspect of the present invention provides an aircraft brake disc that can sufficiently protect a rotary disc against large torque and shock transmitted from a drive key and can sufficiently protect a fixing disc from large torque and shock transmitted from splines, and a method of manufacturing the aircraft brake disc.

According to an aspect of the present invention, there is provided an aircraft brake disc that includes a pressure disc and a rear disc that are disposed at both ends, respectively, and rotary discs and fixing discs that are alternately disposed between the pressure disc and the rear disc, in which drive key grooves that are fitted to drive keys of an aircraft wheel frame are formed with regular intervals around the rotary disc, spline grooves that are fitted to splines of a torque tube of an aircraft brake system are formed with regular intervals around the inner side of a hole of the fixing disc, and the drive key grooves and the spline grooves are coated with an anti-oxidation coating solution including a metal buffer.

According to another aspect of the present invention, there is provided a method of manufacturing an aircraft brake disc that includes: a first step of manufacturing a rotary disc preform for manufacturing a rotary disc and a fixing disc preform for manufacturing a fixing disc; a second step of densifying the rotary disc preform and the fixing disc preform; a third step of forming drive key grooves with regular intervals around the rotary disc preform to be fitted to drive keys of an aircraft wheel frame and of forming spline grooves fitted to splines of a torque tube of an aircraft brake system, with regular intervals around the inner side of a hole of the fixing disc preform; and a fourth step of coating the drive key grooves and the spline grooves with an anti-oxidation coating solution including a metal buffer.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a view simply illustrating an aircraft brake disc according to an embodiment of the present invention;

FIG. 2 is a plan view of the rotary disc illustrated in FIG. 1;

FIG. 3 is a plan view of the fixing disc illustrated in FIG. 1; and

FIG. 4 is a flowchart illustrating a method of manufacturing an aircraft brake disc according to an embodiment of the present invention.

### DETAILED DESCRIPTION OF THE PREFERRED EMBODIMENT

Exemplary embodiments of the present invention will now be described in detail with reference to the accompanying drawings.

Hereinafter, an aircraft brake disc according to an embodiment of the present invention will be described in detail.

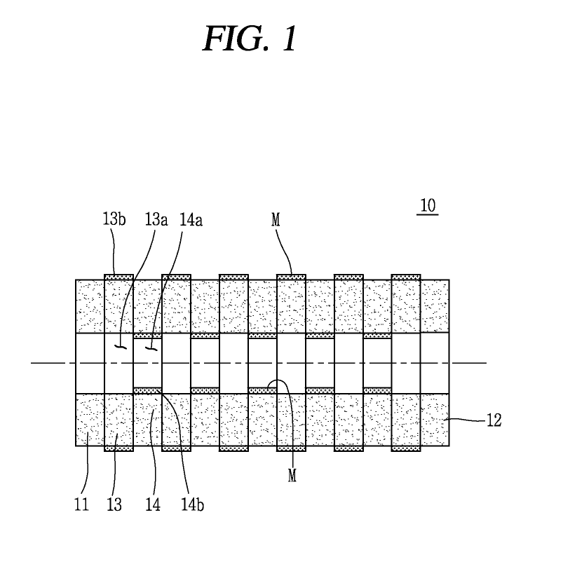

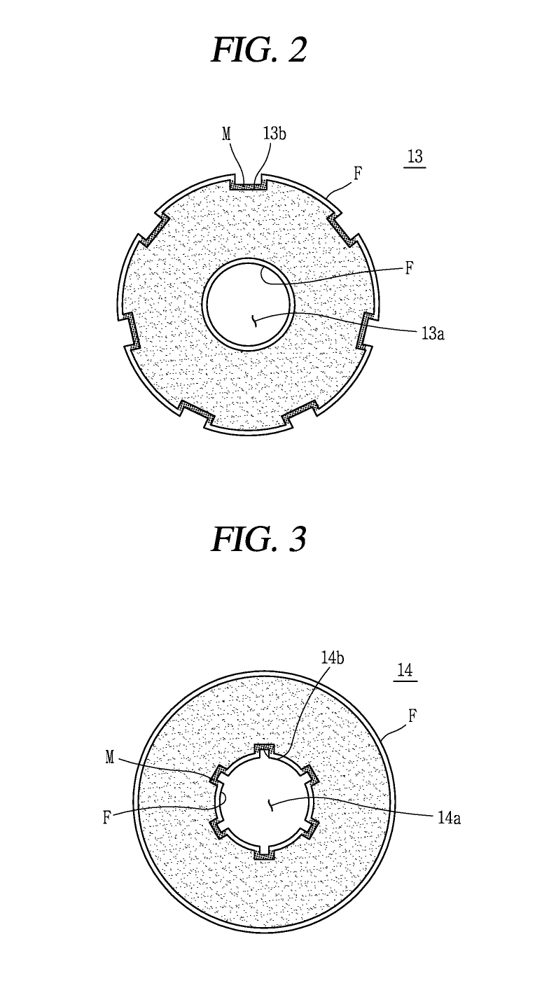

FIG. 1 is a view simply illustrating an aircraft brake disc according to an embodiment of the present invention. To avoid complicity, an anti-oxidation coating layer is not illustrated in FIG. 1. FIG. 2 is a plan view of the rotary disc illustrated in FIG. 1. FIG. 3 is a plan view of the fixing disc illustrated in FIG. 1.

As illustrated in FIG. 1, an aircraft brake disc 10 according to the first embodiment of the present invention includes a pressure disc 11 and a rear disc 12 that are disposed at both ends, respectively, and rotary discs 13 and fixing discs 14 that are alternately disposed between the pressure disc 11 and the rear disc 12.

Referring to FIGS. 1 and 2, a hole 13a in which a torque tube of an aircraft brake system is inserted is formed at the center of the rotary disc 13 and drive key grooves 13b that are fitted to drive keys of an aircraft wheel frame are formed with regular intervals around the rotary disc 13. A hole in which a wheel shaft of an aircraft is inserted is formed at the center of the torque tube.

The inner side of the hole 13a of the rotary disc 13 and the outer side of the rotary disc 13 are coated with an anti-oxidation coating solution. Accordingly, an anti-oxidation coating layer F is formed on the inner side of the hole 13a of the rotary disc 13 and the outer side of the rotary disc 13.

The front and rear sides of the rotary disc 13 rub against the pressure disc 11, the rear disc 13, or the fixing disc 14, so they do not need anti-oxidation coating. The reason is that when a brake operates, the front and rear sides of the rotary disc 13 do not come in contact with oxygen due to friction between the front and rear sides and the pressure disc 11, the rear disc 12, or the fixing disc 14, so there is no concern of oxidation on them. Further, this is because friction force decreases, when anti-oxidation coating is applied to the front and rear sides of the rotary disc 13.

The drive key grooves 13b are coated with a mixture of a metal buffer M and an anti-oxidation coating solution. The metal buffer M may be copper (Cu), silver (Ag), or metal silicon (Si). Alternatively, mixtures of those components may be used.

By using copper, silver, or metal silicon that is softer than steel (Fe) that is rigid for the drive keys, it is possible to reduce torque and shock transmitted from the drive keys. The degree of rigidity and softness may be expressed by a volume modulus. The larger the volume modulus, the more the rigid the material, while the smaller the volume modulus, the softer the material.

The volume modulus of copper, silver, and metal silicon (Si) is 1.25×10³, 8.05×10², and 1.15×10³, respectively. Accordingly, they are smaller than the volume modulus, 2.17×10³, of steel (Fe).

Obviously, gold (Au) or white gold (Pt) having a smaller volume modulus than steel (Fe) may be used, but they are expensive. Therefore, it is advantageous to use copper, silver, and metal silicon.

Referring to FIGS. 1 and 3, a hole 14a in which the torque tube of an aircraft brake system is formed with regular intervals at the center of the fixing disc 14. Splines are formed with regular intervals around the torque tube. Spline grooves 14b fitted on the splines are formed around the inner side of the hole 14a. A hole in which a wheel shaft of an aircraft is inserted is formed at the center of the torque tube.

The inner side of the hole 14a of the fixing disc 14 and the outer side of the fixing disc 14 are coated with an anti-oxidation coating solution. Accordingly, an anti-oxidation coating layer F is formed on the inner side of the hole 14a of the fixing disc 14 and the outer side of the fixing disc 14.

The front and rear sides of the fixing disc 14 rub against the pressure disc 11, the rear disc 12, or the rotary disc 13, so they do not need anti-oxidation coating. The reason is that when a brake operates, the front and rear sides of the fixing disc 14 do not come in contact with oxygen due to friction between the front and rear sides and the pressure disc 11, the rear disc 12, or the rotary disc 13, so there is no concern of oxidation on them. Further, this is because friction force decreases, when anti-oxidation coating is applied to the front and rear sides of the fixing disc 14.

The spline grooves 14b are coated with a mixture of a metal buffer M and an anti-oxidation coating solution. The metal buffer M may be copper (Cu), silver (Ag), or metal silicon (Si). Further, mixture of those components may be used. The reason for using the metal buffer M was described above.

Hereinafter, a method of manufacturing an aircraft brake disc according to an embodiment of the present invention will be described in detail.

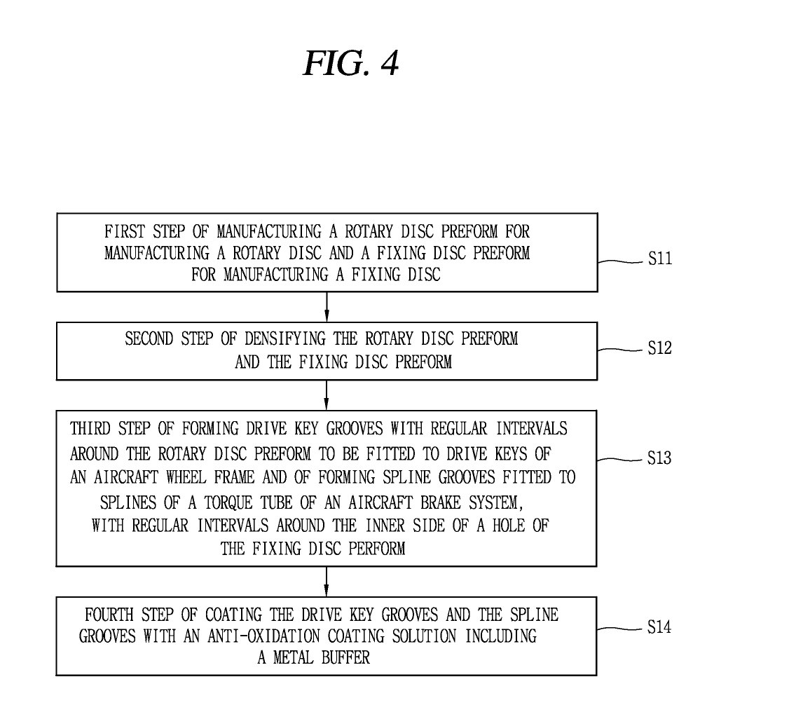

FIG. 4 is a flowchart illustrating a method of manufacturing an aircraft brake disc according to an embodiment of the present invention.

As illustrated in FIG. 4, a method of manufacturing an aircraft brake disc according to an embodiment of the present invention includes: a first step of manufacturing a rotary disc preform for manufacturing a rotary disc and a fixing disc preform for manufacturing a fixing disc (S11); a second step of densifying the rotary disc preform and the fixing disc preform (S12); a third step of forming drive key grooves with regular intervals around the rotary disc preform to be fitted to drive keys of an aircraft wheel frame and of forming spline grooves fitted to splines of a torque tube of an aircraft brake system, with regular intervals around the inner side of a hole of the fixing disc preform (S13); and a fourth step of coating the drive key grooves and the spline grooves with an anti-oxidation coating solution including a metal buffer (S14).

The first step (S11) is described.

A rotary disc preform and a fixing disc preform are formed in the types of a two dimension preform or a three dimension preform.

### Two Dimension Preform

A heat resistant fiber and resin are put into a mold and then mixed therein. An oxi-pan fiber, a carbon fiber, or silicon carbide fiber, or mixtures of them are used for the heat resistant fiber. The resin may be phenol resin, furan resin, coal tar pitch, or petroleum pitch. A preform is obtained by pressing the heat resistant fiber and the resin mixed in the mold and then heating the mixture. The preform is taken out of the mold and then put into a carbonization furnace. The preform is carbonized at a high temperature over 900° C. A carbide with components except carbon removed is obtained. Holes are formed through the center of the rotary disc preform and the center of the fixing disc preform so that an electrode rod can be inserted therein. A rotary disc preform and a fixing disc preform are formed in the types of two dimension preforms in this way.

### Three Dimension Preform

Heat resistant fabrics are formed. The heat resistant fabrics are formed by weaving an oxi-pan fiber, a carbon fiber, or silicon carbide fiber. A staple fiber made of an oxi-pan fiber is applied onto the heat resistant fabrics. The heat resistant fabrics are stacked. Angles such as ±30°, ±45°, ±60°, or ±90° may be given, when the heat resistant fabrics are stacked. The stacked heat resistant fabrics are punched with a needle. The needle moves down with staple fiber. The staple fiber combines the stacked heat resistant fabrics, thereby forming a preform. The preform is taken out of the needle punching equipment and then put into a carbonization furnace. The preform is carbonized at a high temperature over 900° C. A carbide with components except carbon removed is obtained. Holes are formed through the center of the rotary disc preform and the center of the fixing disc preform so that an electrode rod can be inserted therein. A rotary disc preform and a fixing disc preform are formed in the types of three dimension preforms in this way.

The second step (S12) is described.

The rotary disc preform and the fixing disc preform are densified, using thermal gradient chemical vapor deposition or liquid impregnation, or a combination of thermal gradient chemical vapor deposition and liquid impregnation.

### Thermal Gradient Chemical Vapor Deposition

In order to explain the thermal gradient chemical vapor deposition, the rotary disc preform and the fixing disc preform are abbreviated as “preform”. This is the same in the following description.

An electrode rod is inserted into the hole at the center of the preform. The electrode rod is made of graphite. The outer diameter of the electrode rod is 0.2 to 0.5 mm smaller than the inner diameter of the hole at the center of the preform. The electrode rod heats the preform. As heat transfers from the center to the outside of the preform, a thermal gradient is generated in the preform. When the temperature at the center of the preform reaches 700° C. or more, a reaction gas such as methane or propane is supplied. The reaction gas is thermal decomposed. Carbon in the reaction gas is deposited from the center to the outside of the preform. The density of the reaction gas may be 10 to 100 percent and the reaction pressure may be 10 to 10,000 torr. The density of the rotary disc and the density of the fixing disc are increased to 1.7 g/cm³ by depositing carbon to the preform.

### Liquid Impregnation

The liquid impregnation deposits carbon to a preform by repeating several times impregnating and carbonating resin such as pitch or phenol to the preform. The liquid impregnation is performed in an inactive atmosphere at pressure of the atmospheric pressure or less, and temperature of 700 to 1000° C. The liquid impregnation can easily convert a matrix into a graphite structure, using high heat treatment.

The density of the rotary disc and the density of the fixing disc are increased to 1.7 g/cm³ by depositing carbon to the preform.

### Combination of Thermal Gradient Chemical Vapor Deposition and Liquid Impregnation

The density of a three dimension preform is increased to 1.55 to 1.65 g/cm³ by depositing a reaction gas to the preform using thermal gradient chemical vapor deposition. Then, the density of the rotary disc and the density of the fixing disc are increased to 1.7 g/cm³ by depositing carbon to the preform using the liquid impregnation.

The third step (S13) is described.

Referring to FIG. 2, a hole 13a in which a torque tube of an aircraft brake system is inserted are formed by widening the hole at the center of the rotary disc preform 13. Drive key groove 13b fitted to drive keys of an aircraft wheel frame are formed with regular intervals around the rotary disc 13.

Referring to FIG. 3, a hole 14a in which a torque tube of an aircraft brake system is inserted are formed by widening the hole at the center of the fixing disc preform 14. Spline grooves 14b fitted to splines of the torque tube are formed around the inner side of the hole 14a.

The fourth step (S14) is described.

The anti-oxidation coating solution is a compound including boron. The compound is composed of B, BN, H₃PO₄,(Mn(H₃PO₄)₂2H₂O), KOH, SiO₂, and NH₃.

Referring to FIG. 3, the inner side of the hole 13a of the rotary disc 13 and the outer side of the rotary disc 13 are coated with an anti-oxidation coating solution. The anti-oxidation coating solution is applied by a brush or a spray to the inner side of the hole 13a of the rotary disc 13 and the outer side of the rotary disc 13.

The drive key grooves 13b is coated with a mixture of a metal buffer M and an anti-oxidation coating solution. The kinds of the metal buffer M and the reason for using the metal buffer M were described above.

Accordingly, an anti-oxidation coating layer F is formed on the inner side of the hole 13a of the rotary disc 13 and the outer side of the rotary disc 13. An anti-oxidation coating layer F mixed with the metal buffer M is formed on the drive key grooves 13b.

Referring to FIG. 4, the inner side of the hole 14a of the fixing disc 14 and the outer side of the fixing disc 14 are coated with an anti-oxidation coating solution. The anti-oxidation coating solution is applied by a brush or a spray to the inner side of the hole 14a of the fixing disc 14 and the outer side of the fixing disc 14.

The spline grooves 14b are coated with a mixture of a metal buffer M and an anti-oxidation coating solution. The kinds of the metal buffer M and the reason for using the metal buffer M were described above.

Accordingly, an anti-oxidation coating layer F is formed on the inner side of the hole 14a of the fixing disc 14 and the outer side of the fixing disc 14. An anti-oxidation coating layer F mixed with the metal buffer M is formed on the spline grooves 14b.

As set forth above, according to exemplary embodiments of the invention, a metal buffer attached to drive key groove of a rotary disc can reduce torque and shock transmitted from drive keys of an aircraft wheel frame. Accordingly, the rotary disc can be sufficiently protected from torque and shock.

Further, according to the present invention, a metal buffer attached to spline grooves of a fixing disc can reduce torque and shock transmitted from splines of a torque tube of an aircraft brake system. Accordingly, the fixing disc can be sufficiently protected from torque and shock.

While the present invention has been illustrated and described in connection with the exemplary embodiments, it will be apparent to those skilled in the art that modifications and variations can be made without departing from the spirit and scope of the invention as defined by the appended claims.

What is claimed is:

1. A method of manufacturing an aircraft brake disc, comprising:
a first step of manufacturing a rotary disc preform for manufacturing a rotary disc and a fixing disc preform for manufacturing a fixing disc;
a second step of densifying the rotary disc preform and the fixing disc preform;
a third step of forming drive key grooves with regular intervals around the rotary disc preform to be fitted to drive keys of an aircraft wheel frame and of forming spline grooves fitted to splines of a torque tube of an aircraft brake system, with regular intervals around the inner side of a hole of the fixing disc preform; and
a fourth step of coating the drive key grooves and the spline grooves with an anti-oxidation coating solution including a metal buffer.

2. The method of claim 1, wherein in the first step, the rotary disc preform and the fixing disc preform are formed in the types of a two dimension preform or a three dimension preform.

3. The method of claim 1, wherein in the second step, the rotary disc preform and the fixing disc preform are densified, using thermal gradient chemical vapor deposition or liquid impregnation, or a combination of thermal gradient chemical vapor deposition and liquid impregnation.

4. The method of claim 1, wherein in the fourth step, the anti-oxidation coating solution is a compound which is composed of B, BN, H₃PO₄, (Mn(H₃PO₄)₂2H₂O), KOH, SiO₂, and NH₃.

5. The method of claim 1, wherein in the fourth step, the anti-oxidation coating solution is applied by a brush or a spray to the drive key grooves and the spline grooves.

6. The method of claim 1, wherein in the fourth step, the metal buffer is any one of copper (Cu), silver (Ag), and metal silicon (Si).

7. The method of claim 1, wherein in the fourth step, the metal buffer is a mixture of copper (Cu), silver (Ag), and metal silicon (Si).

8. An aircraft brake disc manufactured by the method of manufacturing an aircraft brake disc according to claim 1.
